(19) United States
(12) Patent Application Publication
(10) Pub. No.: US 2023/0126379 A1
(43) Pub. Date: Apr. 27, 2023

(54) SYSTEMS AND METHODS FOR DETECTING CURRENTS OF POWER MANAGEMENT SYSTEMS

(71) Applicant: ON-BRIGHT ELECTRONICS (SHANGHAI) CO., LTD., Shanghai (CN)

(72) Inventors: ZHIQIN ZHAO, Shanghai (CN); Qiang LUO, Shanghai (CN)

(21) Appl. No.: 17/975,293

(22) Filed: Oct. 27, 2022

(30) Foreign Application Priority Data
Oct. 27, 2021 (CN) 202111255368.9

(51) Int. Cl. G01R 19/00; H02M 1/00

(52) U.S. Cl. CPC G01R 19/0092; H02M 1/0009

(57) ABSTRACT

System and method for detecting one or more currents. For example, a system for detecting one or more currents includes: one or more current sampling units coupled to one or more terminal transistors respectively and configured to sample one or more terminal currents that flow between a system terminal of a power management system and one or more port terminals through the one or more terminal transistors respectively; one or more operational amplifiers coupled to the one or more current sampling units respectively and configured to generate one or more detection currents respectively, the one or more detection currents representing one or more magnitudes of the one or more terminal currents respectively; and a signal combiner configured to receive the one or more detection currents, generate a combined detection voltage representing a sum of the one or more magnitudes of the one or more terminal currents.

### 1. CROSS-REFERENCES TO RELATED APPLICATIONS

This application claims priority to Chinese Patent Application No. 202111255368.9, filed Oct. 27, 2021, incorporated by reference herein for all purposes.

### 2. BACKGROUND OF THE INVENTION

Certain embodiments of the present invention are directed to circuits. More particularly, some embodiments of the invention provide systems and methods for detecting currents. Merely by way of example, some embodiments of the invention have been applied to power management systems. But it would be recognized that the invention has a much broader range of applicability.

For a conventional power management system, the input current and/or the output current often needs to be detected in order to regular the input current and/or the output current respectively. For example, the input current usually is determined by detecting the voltage across a resistor connected between an input terminal of the power management system and a terminal that is connected to a power source, and then the determined input current is used by a main feedback loop of the power management system to regulate the input current in order to keep the input current at a constant magnitude. As an example, the output current usually is determined by detecting the voltage across a resistor connected between an output terminal of the power management system and a terminal that is connected to a load device, and then the determined output current is used by a main feedback loop of the power management system to regulate the output current in order to keep the output current at a constant magnitude.

FIG. 1 is a simplified diagram showing a conventional current detection system as part of a charging system. The conventional current detection system includes one or more resistors 110₁, 110₂, . . . , and 110_{N}, one or more operational amplifiers 120₁, 120₂, . . . , and 120_{N}, and a signal combiner 130. In addition to the conventional current detection system, the charging system 100 also includes a power management system 102 and one or more transistors 180₁, 180₂, . . . and 180_{N}, and one or more terminals 190₁, 190₂, . . . , and 190_{N}. The power management system 102 includes a power supply 140, a power converter 150, an output inductor 160, and an output capacitor 170. As shown in FIG. 1, the charging system 100 includes the one or more resistors 110₁, 110₂, . . . , and 110_{N}, the one or more operational amplifiers 120₁, 120₂, . . . , and 120_{N}, the one or more transistors 180₁, 180₂, . . . , and 180_{N}, and the one or more terminals 190₁, 190₂, . . . , and 190_{N}, wherein N is a positive integer. For example, N is equal to 1. As an example, N is larger than 1.

The conventional current detection system is configured to regulate a current 103 that flows out of the power management system 102 at a terminal 104. As part of the power management system 102, the power supply 140 provides a voltage 141 to the power converter 150. In response, the power converter 150 (e.g., a DC-DC converter) generates a voltage 151, which is used by the output inductor 160 and the output capacitor 170 to generate a voltage 105 at the terminal 104. Additionally, the power converter 150 (e.g., a DC-DC converter) also generates a control signal 153. One terminal of the output capacitor 170 is biased to a ground voltage 171.

The terminal 104 is connected to a terminal 112ᵢ of the resistor 110ᵢ and connected to an input terminal 122ᵢ (e.g., an “+” terminal) of the operational amplifier 120ᵢ, wherein i is an integer larger than or equal to 1 but smaller than or equal to N. The resistor 110ᵢ also includes a terminal 114ᵢ, and the operational amplifier 120ᵢ also includes an input terminal 124ᵢ (e.g., an “−” terminal) and an output terminal 126ᵢ. The terminal 114ᵢ of the resistor 110ᵢ and the input terminal 124ᵢ (e.g., an “−” terminal) of the operational amplifier 120ᵢ are connected. The terminal 114ᵢ of the resistor 110ᵢ is also connected to a drain terminal 184ᵢ of the transistor 180ᵢ, which also includes a gate terminal 182ᵢ and a source terminal 186ᵢ. The gate terminal 182ᵢ of the transistor 180ᵢ receives a signal 181ᵢ, and the source terminal 186ᵢ of the transistor 180ᵢ is connected to the terminal 190ᵢ (e.g., a port terminal). For example, the control signal 153 includes the signal 181ᵢ, which is used to turn on and/or turn off the transistor 180ᵢ. As an example, the port terminal 190ᵢ is used to charge a load device.

The operational amplifier 120ᵢ receives a voltage from the terminal 112ᵢ of the resistor 110ᵢ and also receives a voltage from the terminal 114ᵢ of the resistor 110ᵢ and in response generates a detection signal 127ᵢ. The detection signal 127ᵢ represents a magnitude of a current 115ᵢ that flows from the terminal 104 to the terminal 190ᵢ through the resistor 110ᵢ and the transistor 180ᵢ. The signal combiner 130 receives the detection signal 127ᵢ and in response generates a combined detection voltage 131. The combined detection voltage 131 represents a sum of the magnitude of the current 115ᵢ, the magnitude of the current 115₂, . . . , and the magnitude of the current 115_{N}. The sum of the magnitude of the current 115₁, the magnitude of the current 115₂, . . . , and the magnitude of the current 115_{N} is equal to the magnitude of the current 103 that flows out of the power management system 102 at the terminal 104. The combined detection voltage 131 represents the magnitude of the current 103. The power converter 150 receives the combined detection voltage 131 and uses the combined detection voltage 131 to regulate the magnitude of the current 103 in order to keep the magnitude of the current 103 at a constant level.

The detection signal 127, is a current that represents a magnitude of the current 115, that flows from the terminal 104 to the terminal 190, through the transistor 180ᵢ. The signal combiner 130 receives the detection current 12′71, the detection current 1272, . . . , and the detection current 127_{N} and generates a combined detection current that is equal to a sum of the detection current 12′71, the detection current 1272, . . . , and the detection current 127_{N}. As an example, the combined detection current flows through a resistor that is a part of the signal combiner 130 to convert the combined detection current to the combined detection voltage 131.

As discussed above, the conventional current detection system is used to establish a stable magnitude for the current 103 that flows out of the power management system 102 by detecting one or more voltages across the one or more resistors 1101 , 1102 , . . . , and 110N respectively, amplifying the one or more detected voltages to generate the one or more detection voltages 12′71, 1272, . . . , and 127_{N}, combining the one or more detection voltages 127₁, 127₂, . . . , and 127_{N} to generate the combined detection voltage 131, and providing the combined detection voltage 131 to the main loop in order to regulate the magnitude of the current 103. In some examples, N is equal to 1. For example, the charging system 100 includes the resistor 110₁, the operational amplifier 120₁, the transistor 180₁, and the terminal 190₁. As an example, example, i is equal to 1, and i cannot be larger than 1.

Referring to FIG. 1, for example, the conventional current detection system is used to detect a current that is received by the power management system 102. As an example, the power management system 102 does not include the power supply 140, which is external to the power management system 102. Also, referring to FIG. 1, if the DC-DC converter 150 is replaced by an AC-DC converter, the output inductor 160 is replaced by a transformer and the output capacitor 170 is replaced by a rectifier circuit on the secondary side.

The use of the one or more resistors 110₁, 110₂, . . . , and 110_{N} often cause circuit loss and also reduce efficiency of the charging system 100. In order to reduce circuit loss, each resistor of the one or more resistors 110₁, 110₂, . . . , and 110_{N} has a small resistance value (e.g., 5 mΩ). Also, conventional clock signal generators often use an input clock signal to generate a clock signal at a lower voltage level and then use a level shifter to convert the clock signal at the lower voltage level to another clock signal at a higher voltage level, but the clock signal at the lower voltage level and the clock signal at the higher voltage usually cannot be kept completely synchronized for a wide voltage range.

Hence it is highly desirable to improve the technique for current detection of a charging system.

### 3. BRIEF SUMMARY OF THE INVENTION

Certain embodiments of the present invention are directed to circuits. More particularly, some embodiments of the invention provide systems and methods for detecting currents. Merely by way of example, some embodiments of the invention have been applied to power management systems. But it would be recognized that the invention has a much broader range of applicability.

According to some embodiments, a system for detecting one or more currents includes: one or more current sampling units coupled to one or more terminal transistors respectively and configured to sample one or more terminal currents that flow between a system terminal of a power management system and one or more port terminals through the one or more terminal transistors respectively; one or more operational amplifiers coupled to the one or more current sampling units respectively and configured to generate one or more detection currents respectively, the one or more detection currents representing one or more magnitudes of the one or more terminal currents respectively; and a signal combiner configured to receive the one or more detection currents, generate a combined detection voltage representing a sum of the one or more magnitudes of the one or more terminal currents, and output the combined detection voltage to the power management system to regulate the sum of the one or more magnitudes of the one or more terminal currents.

According to certain embodiments, a chopper amplifier includes: a ground voltage generator configured to receive a first ground voltage and a system voltage and generate a second ground voltage based at least in part on the first ground voltage and the system voltage; a clock signal generator configured to receive an input clock signal, the first ground voltage and the second ground voltage and generate a first clock signal and a second clock signal based at least in part on the input clock signal, the first ground voltage and the second ground voltage; and a chopper and amplification unit including a first chopper unit, a second chopper unit coupled to the first chopper unit through multiple transistors, and a third chopper unit coupled to the second chopper unit through multiple transistors; wherein: the second ground voltage is higher than or equal to the first ground voltage; wherein: if the first clock signal is equal to the first ground voltage, the first clock signal is at a logic low level; and if the second clock signal is equal to the second ground voltage, the second clock signal is at the logic low level; wherein: the first chopper unit is configured to receive the second clock signal; the second chopper unit is configured to receive the second clock signal; and the third chopper unit is configured to receive the first clock signal.

According to some embodiments, a method for detecting one or more currents includes: sampling one or more terminal currents that flow between a system terminal of a power management system and one or more port terminals through one or more terminal transistors respectively; generating one or more detection currents representing one or more magnitudes of the one or more terminal currents respectively; receiving the one or more detection currents; generating a combined detection voltage representing a sum of the one or more magnitudes of the one or more terminal currents; and outputting the combined detection voltage to the power management system to regulate the sum of the one or more magnitudes of the one or more terminal currents.

Depending upon embodiment, one or more benefits may be achieved. These benefits and various additional objects, features and advantages of the present invention can be fully appreciated with reference to the detailed description and accompanying drawings that follow.

### 4. BRIEF DESCRIPTION OF THE DRAWINGS

FIG. 1 is a simplified diagram showing a conventional current detection system as part of a charging system.

FIG. 2 is a simplified diagram showing a current detection system as part of a charging system according to certain embodiments of the present invention.

FIG. 3 is a simplified diagram showing certain components of the current sampling unit, the operational amplifier, and the signal combiner of the current detection system as part of the charging system as shown in FIG. 2 according to some embodiments of the present invention.

FIG. 4 is a simplified diagram showing certain components of the chopper amplifier of the operational amplifier of the current detection system as part of the charging system as shown in FIG. 2 and FIG. 3 according to certain embodiments of the present invention.

FIG. 5 is a simplified diagram showing certain components of the clock signal generator of the chopper amplifier of the operational amplifier of the current detection system as part of the charging system as shown in FIG. 2, FIG. 3 and FIG. 4 according to certain embodiments of the present invention.

FIG. 6 is a simplified diagram showing certain components of the virtual ground voltage generator of the chopper amplifier of the operational amplifier of the current detection system as part of the charging system as shown in FIG. 2, FIG. 3 and FIG. 4 according to some embodiments of the present invention.

### 5. DETAILED DESCRIPTION OF THE INVENTION

Certain embodiments of the present invention are directed to circuits. More particularly, some embodiments of the invention provide systems and methods for detecting currents. Merely by way of example, some embodiments of the invention have been applied to power management systems. But it would be recognized that the invention has a much broader range of applicability.

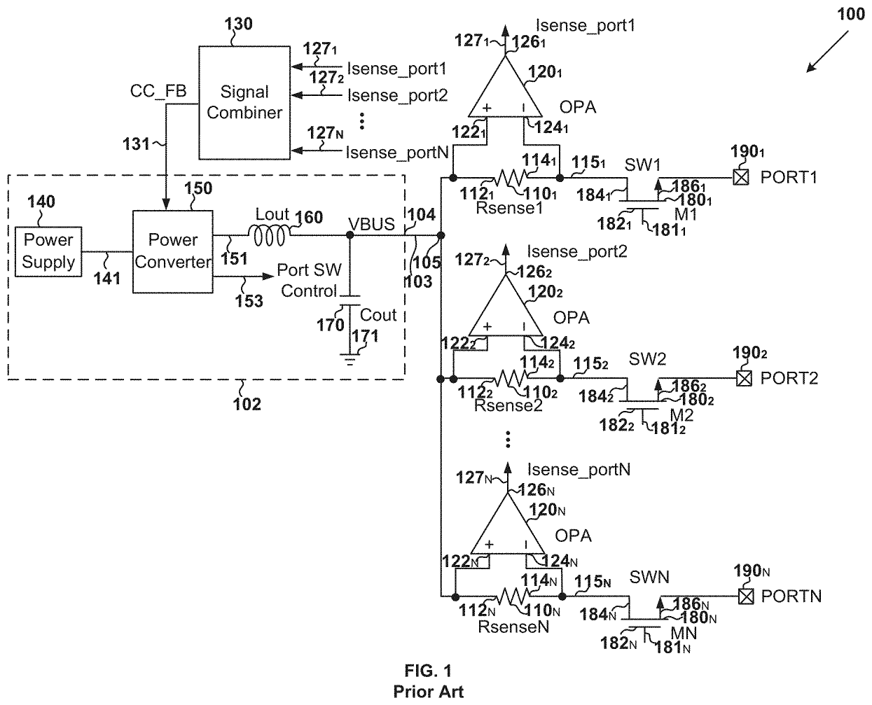

As shown in FIG. 1, for the conventional current detection system, the one or more current sampling resistors 110₁, 110₂, . . . , and 110_{N} need to be provided for the one or more terminals 190₁, 190₂, . . . , and 190_{N} respectively according to certain embodiments. For example, the use of the one or more current sampling resistors 110₁, 110₂, . . . , and 110_{N} increases bill of materials (BOM), increases circuit loss, and/or reduces circuit efficiency. As another example, to reduce circuit loss, each resistor of the one or more resistors 110₁, 110₂, . . . , and 110_{N} has a small resistance value (e.g., 5 mΩ).

According to some embodiments, if the resistance value of each resistor of the one or more resistors 110₁, 110₂, . . . , and 110_{N} is small, when the magnitude of the current 115ᵢ is small, the voltage received by the terminal 122ᵢ minus the voltage received by the terminal 124ᵢ is also small, reducing signal-to-noise ratio and/or reducing detection accuracy for small currents. For example, when the terminal 190ᵢ needs the current 115ᵢ to be small, the conventional current detection system as shown in FIG. 1 often cannot meet the requirements of the charging system 100. As an example, a wide range for the voltage 105 usually further reduces the detection accuracy for small currents, so that the detection accuracy often is worse than ±50%.

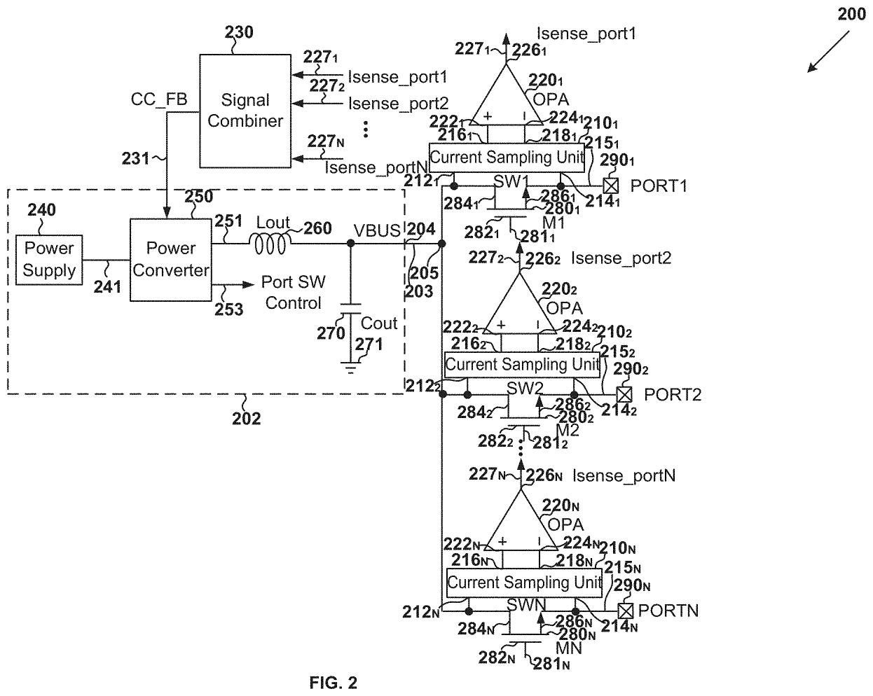

FIG. 2 is a simplified diagram showing a current detection system as part of a charging system according to certain embodiments of the present invention. This diagram is merely an example, which should not unduly limit the scope of the claims. One of ordinary skill in the art would recognize many variations, alternatives, and modifications. The current detection system includes one or more current sampling units 210₁, 210₂, . . . , and 210_{N}, one or more operational amplifiers 220₁, 220₂, . . . , and 220_{N}, and a signal combiner 230. For example, in addition to the current detection system, the charging system 200 also includes a power management system 202 and one or more transistors 280₁, 280₂, ... and 280_{N}, and one or more terminals 290₁, 290₂, . . . , and 290_{N}. As an example, the power management system 202 includes a power supply 240, a power converter 250, an output inductor 260, and an output capacitor 270. As shown in FIG. 2, the charging system 200 includes the one or more current sampling units 210₁, 210₂, . . . , and 210_{N}, the one or more operational amplifiers 220₁, 220₂, . . . , and 220_{N}, the one or more transistors 280₁, 280₂, ... and 280_{N}, and the one or more terminals 290₁, 290₂, . . . , and 290_{N}, wherein N is a positive integer, according to some embodiments. For example, N is equal to 1. As an example, N is larger than 1. Although the above has been shown using a selected group of components for the current detection system, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

In certain embodiments, the current detection system is configured to regulate a current 203 that flows out of the power management system 202 at a terminal 204. For example, as part of the power management system 202, the power supply 240 provides a voltage 241 to the power converter 250. As an example, in response, the power converter 250 (e.g., a DC-DC converter) generates a voltage 251, which is used by the output inductor 260 and the output capacitor 270 to generate a voltage 205 at the terminal 204. For example, additionally, the power converter 250 (e.g., a DC-DC converter) also generates a control signal 253. As an example, one terminal of the output capacitor 270 is biased to a ground voltage 271.

In some embodiments, the terminal 204 is connected to a drain terminal 284ᵢ of the transistor 280ᵢ and an input terminal 212ᵢ of the current sampling unit 210ᵢ, wherein i is an integer larger than or equal to 1 but smaller than or equal to N. For example, the transistor 280ᵢ also includes a gate terminal 282ᵢ and a source terminal 286ᵢ. As an example, the current sampling unit 210ᵢ also includes an input terminal 214ᵢ, an output terminal 216ᵢ, and an output terminal 218ᵢ. In certain examples, the input terminal 214ᵢ of the current sampling unit 210ᵢ is connected to the source terminal 286ᵢ of the transistor 280ᵢ and is also connected to the terminal 290ᵢ (e.g., a port terminal). For example, the port terminal 290ᵢ is used to charge a load device. As an example, the gate terminal 282ᵢ of the transistor 280ᵢ receives a signal 281ᵢ, which is a part of the control signal 253 and is used to turn on and/or turn off the transistor 280ᵢ. In some examples, the output terminal 216ᵢ of the current sampling unit 210ᵢ is connected to an input terminal 222ᵢ (e.g., an “+” terminal) of the operational amplifier 220ᵢ, and the output terminal 218ᵢ of the current sampling unit 210ᵢ is connected to an input terminal 224ᵢ (e.g., an “−” terminal) of the operational amplifier 220ᵢ. For example, the operational amplifier 220ᵢ also includes an output terminal 226ᵢ.

According to certain embodiments, the operational amplifier 220ᵢ generates a detection signal 227ᵢ at the output terminal 226ᵢ. For example, the detection signal 227ᵢ represents a magnitude of a current 215ᵢ that flows from the terminal 204 to the terminal 290ᵢ through the transistor 280ᵢ. In some examples, the signal combiner 230 receives the detection signal 227ᵢ and in response generates a combined detection voltage 231. For example, the combined detection voltage 231 represents a sum of the magnitude of the current 215ᵢ, the magnitude of the current 215₂, . . . , and the magnitude of the current 215_{N}. In certain examples, the sum of the magnitude of the current 215₁, the magnitude of the current 215₂, . . . , and the magnitude of the current 215_{N} is equal to the magnitude of the current 203 that flows out of the power management system 202 at the terminal 204. For example, the combined detection voltage 231 represents the magnitude of the current 203. As an example, the power converter 250 receives the combined detection voltage 231 and uses the combined detection voltage 231 to regulate the magnitude of the current 203 in order to keep the magnitude of the current 203 at a constant level.

In some examples, the detection signal 227ᵢ is a current that represents a magnitude of the current 215ᵢ that flows from the terminal 204 to the terminal 290ᵢ through the transistor 280ᵢ. For example, the signal combiner 230 receives the detection current 227₁, the detection current 227₂, . . . , and the detection current 227_{N} and generates a combined detection current that is equal to a sum of the detection current 227₁, the detection current 227₂, . . . , and the detection current 227_{N}. As an example, the combined detection current flows through a resistor that is a part of the signal combiner 230 to convert the combined detection current to the combined detection voltage 231.

According to some embodiments, as shown in FIG. 2, the current detection system is used to establish a stable magnitude for the current 203 that flows out of the power management system 202 by detecting the one or more currents 215₁, 215₂, . . . , and 215_{N} to generate the one or more detection voltages 227₁, 227₂, . . . , and 227_{N}, combining the one or more detection voltages 227₁, 227₂, . . . , and 227_{N} to generate the combined detection voltage 231, and providing the combined detection voltage 231 to the main loop in order to regulate the magnitude of the current 203. For example, the current sampling unit 210ᵢ uses the input terminals 212ᵢ and 214ᵢ to sample the current 215ᵢ that flows from the terminal 204 to the terminal 290ᵢ through the transistor 280ᵢ. As an example, the operational amplifier 220ᵢ in response generates the detection signal 227ᵢ, which represents the magnitude of the current 215ᵢ that flows from the terminal 204 to the terminal 290ᵢ through the transistor 280ᵢ.

In certain embodiments, the operational amplifier 220ᵢ is configured to perform a chopper function and/or amply a current with a predetermined constant ratio. For example, the operational amplifier 220ᵢ includes a chopper amplifier that is configured to process high voltages and also includes a digital-to-analog converter (DAC).

As discussed above and further emphasized here, FIG. 2 is merely an example, which should not unduly limit the scope of the claims. One of ordinary skill in the art would recognize many variations, alternatives, and modifications. In some embodiments, N is equal to 1. For example, the charging system 200 includes the current sampling unit 210₁, the operational amplifier 220₁, the transistors 280, and the terminal 290₁. As an example, i is equal to 1, and i cannot be larger than 1. In certain embodiments, the current detection system is used to detect a current that is received by the power management system 202. For example, the power management system 202 does not include the power supply 240, which is external to the power management system 202. In some embodiments, if the DC-DC converter 250 is replaced by an AC-DC converter, the output inductor 260 is replaced by a transformer and the output capacitor 270 is replaced by a rectifier circuit on the secondary side.

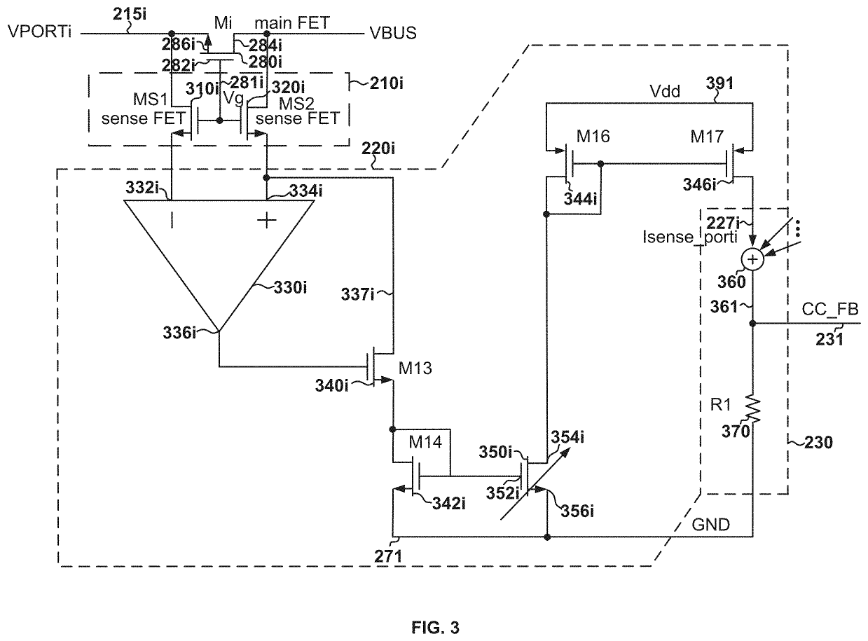

FIG. 3 is a simplified diagram showing certain components of the current sampling unit 210ᵢ, the operational amplifier 220ᵢ, and the signal combiner 230 of the current detection system as part of the charging system 200 as shown in FIG. 2 according to some embodiments of the present invention. This diagram is merely an example, which should not unduly limit the scope of the claims. One of ordinary skill in the art would recognize many variations, alternatives, and modifications. The current sampling unit 210ᵢ includes a transistor 310ᵢ and a transistor 320ᵢ. The operational amplifier 220ᵢ includes a chopper amplifier 330ᵢ, a transistor 340ᵢ, a transistor 342ᵢ, a transistor 344ᵢ, a transistor 346ᵢ, and a digital-to-analog converter (DAC) 350ᵢ. The signal combiner 230 includes a current combiner 360 and a resistor 370. For example, i is an integer larger than or equal to 1 but smaller than or equal to N. As an example, N is a positive integer. Although the above has been shown using a selected group of components for the current detection system, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

In certain embodiments, the current sampling unit 210ᵢ includes the transistor 310ᵢ (e.g., a field-effect transistor) and the transistor 320ᵢ. (e.g., a field-effect transistor). For example, a drain terminal of the transistor 310ᵢ is connected to the source terminal 286ᵢ of the transistor 280ᵢ and the terminal 290ᵢ, and a drain terminal of the transistor 320ᵢ is connected to the drain terminal 284ᵢ of the transistor 280ᵢ and the terminal 204. As an example, the gate terminal of the transistor 310ᵢ and the gate terminal of the transistor 320ᵢ are connected to the gate terminal 282ᵢ of the transistor 280ᵢ. In some examples, the gate terminal of the transistor 310ᵢ, the gate terminal of the transistor 320ᵢ, and the gate terminal 282ᵢ of the transistor 280ᵢ all receive the signal 281ᵢ. For example, the transistor 310ᵢ, the transistor 320ᵢ, and the transistor 280ᵢ are all turned on if the signal 281ᵢ is at a logic high level. As an example, the transistor 310ᵢ, the transistor 320ᵢ, and the transistor 280ᵢ are all turned off if the signal 281ᵢ is at a logic low level. In certain examples, the source terminal of the transistor 310ᵢ is connected to an inverting input terminal 332ᵢ (e.g., the “−” terminal) of the chopper amplifier 330ᵢ, and the source terminal of the transistor 320ᵢ is connected to a non-inverting input terminal 334ᵢ (e.g., the “+” terminal) of the chopper amplifier 330ᵢ. For example, the transistor 280ᵢ, the transistor 310ᵢ and the transistor 320ᵢ each are an NMOS transistor. As an example, the size of the transistor 310ᵢ and the size of the transistor 320ᵢ are the same, equal to the size of the transistor 280ᵢ multiplied by a predetermined ratio.

In some embodiments, the chopper amplifier 330ᵢ also includes an output terminal 336ᵢ. For example, the output terminal 336ᵢ of the chopper amplifier 330ᵢ is connected to a gate terminal of the transistor 340ᵢ, which also includes a drain terminal and a source terminal. As an example, the drain terminal of the transistor 340ᵢ is connected to the source terminal of the transistor 320ᵢ and the non-inverting input terminal 334ᵢ (e.g., the “+” terminal) of the chopper amplifier 330ᵢ, and the source terminal of the transistor 340ᵢ is connected to a drain terminal and a gate terminal of the transistor 342ᵢ. In certain examples, the gate terminal of the transistor 342ᵢ is also connected to a terminal 352ᵢ of the digital-to-analog converter (DAC) 350ᵢ, which also includes a terminal 354ᵢ and a terminal 356ᵢ. For example, the terminal 356ᵢ of the digital-to-analog converter (DAC) 350ᵢ and a source terminal of the transistor 342ᵢ are biased to the ground voltage 271. As an example, the terminal 354ᵢ of the digital-to-analog converter (DAC) 350ᵢ are connected to a drain terminal and a gate terminal of the transistor 344ᵢ. In some examples, the gate terminal of the transistor 344ᵢ is also connected to a gate terminal of the transistor 346ᵢ. For example, a source terminal of the transistor 344ᵢ and a source terminal of the transistor 346ᵢ both are biased to a supply voltage 391. As an example, a drain terminal of the transistor 346ᵢ provides a detection signal 227ᵢ, which is a current that flows out of the drain terminal of the transistor 346ᵢ.

According to certain embodiments, the chopper amplifier 330ᵢ operates in a closed loop with transistor 340ᵢ so that the inverting input terminal 332ᵢ (e.g., the “−” terminal) and the non-inverting input terminal 334ᵢ (e.g., the “+” terminal) of the chopper amplifier 330ᵢ are at the same voltage level. For example, the non-inverting input terminal 334ᵢ (e.g., the “+” terminal) of the chopper amplifier 330ᵢ serves as the input terminal 222ᵢ (e.g., the “+” terminal) of the operational amplifier 220ᵢ. As an example, the inverting input terminal 332ᵢ (e.g., the “−” terminal) of the chopper amplifier 330ᵢ serves as the input terminal 224ᵢ (e.g., the “−” terminal) of the operational amplifier 220ᵢ. In some examples, a current 337ᵢ that flows through the transistor 340ᵢ is equal to the current 215ᵢ multiplied by a predetermined constant. For example, the current 337ᵢ is a sampling current of the current 215ᵢ. In certain examples, the transistor 340ᵢ, the transistor 342ᵢ, the transistor 344ᵢ, and the transistor 346ᵢ are parts of a current mirror. For example, the current mirror receives a current 337ᵢ and generates the detection current 227ᵢ.

According to some embodiments, the detection current 227ᵢ is determined as follows:

$${I}_{227 i} = \frac{{I}_{215 i} \times {R}_{o n i}}{{R}_{s n s i}} \times {α}_{i} = \frac{{I}_{215 i}}{{N}_{i}} \times {α}_{i} \qquad ( Equation 1 )$$

where I₂₂₇ᵢ represents the detection current 227ᵢ, and I₂₁₅ᵢ represents the current 215ᵢ. Additionally, Rₒₙᵢ represents the on resistance of the transistor 280ᵢ, and Rₛₙₛᵢ represents the on resistance of the transistor 310ᵢ or the on resistance of the transistor 320ᵢ, wherein the on resistance of the transistor 310ᵢ and the on resistance of the transistor 320ᵢ are equal. Moreover, Nᵢ represents a ratio of the size of the transistor 280ᵢ to the size of the transistor 310ᵢ or a ratio of the size of the transistor 280ᵢ to the size of the transistor 320ᵢ, wherein the size of the transistor 310ᵢ and the size of the transistor 320ᵢ are equal. Also, αᵢ represents the current ratio of the current mirror that includes the transistor 340ᵢ, the transistor 342ᵢ, the transistor 344ᵢ, and the transistor 346ᵢ.

In certain examples, the current ratio αᵢ of the current mirror is equal to the detection current 227ᵢ divided by the current 337ᵢ. For example, the current ratio αᵢ of the current mirror is adjusted by the digital-to-analog converter (DAC) 350ᵢ. In some examples, as shown by Equation 1, the detection current 227ᵢ depends on the ratio Nᵢ of the size of the transistor 280ᵢ to the size of the transistor 310ᵢ or of the size of the transistor 280ᵢ to the size of the transistor 320ᵢ and also depends on the current ratio αᵢ of the current mirror that includes the transistor 340ᵢ, the transistor 342ᵢ, the transistor 344ᵢ, and the transistor 346ᵢ.

In some examples, the signal combiner 230 includes the current combiner 360 and the resistor 370. For example, the current combiner 360 receives the one or more detection currents 227₁, 227₂, . . . , and 227_{N} and generate a combined current 361. As an example, the combined current 361 is determined as follows:

I₃₆₁=Σᵢ₌₁^{N}I₂₂₇ᵢ (Equation 2)

where I₃₆₁ represents the combined current 361, and I₂₂₇ᵢ represents the detection current 227ᵢ. For example, N is equal to 1. As an example, N is a positive integer larger than 1.

As shown in FIG. 3, the combined current 361 flows through the resistor 370 to generate the combined detection voltage 231 according to certain embodiments. In some examples, the combined detection voltage 231 is determined as follows:

V₂₃₁=I₃₆₁×R₃₇₀=(Σhd i=1^{N}I₂₂₇ᵢ)×R₃₇₀ (Equation 3)

where V₂₃₁ represents the combined detection voltage 231, and I₃₆₁ represents the combined current 361. Additionally, R₃₇₀ represents the resistance of the resistor 370, and I₂₂₇ᵢ represents the detection current 227ᵢ. For example, N is equal to 1. As an example, N is a positive integer larger than 1. In certain examples, based on Equation 3,

V₂₃₁=(I₂₂₇₁+I₂₂₇₂+ . . . +I_{227N})×R₃₇₀ (Equation 4)

where V₂₃₁ represents the combined detection voltage 231 and R₃₇₀ represents the resistance of the resistor 370. Additionally, I₂₂₇₁, I₂₂₇₂, . . . , and I_{227N} represent the one or more detection currents 227₁, 227₂, . . . , and 227_{N} respectively. For example, N is equal to 1. As an example, N is a positive integer larger than 1.

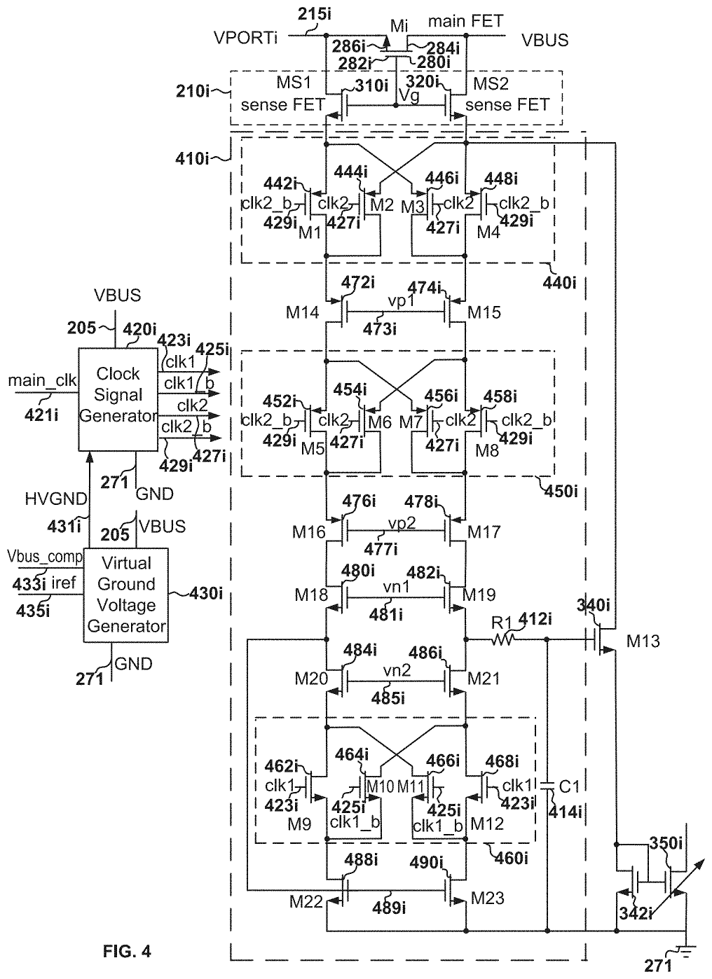

FIG. 4 is a simplified diagram showing certain components of the chopper amplifier 330ᵢ of the operational amplifier 220ᵢ of the current detection system as part of the charging system 200 as shown in FIG. 2 and FIG. 3 according to certain embodiments of the present invention. This diagram is merely an example, which should not unduly limit the scope of the claims. One of ordinary skill in the art would recognize many variations, alternatives, and modifications. The chopper amplifier 330, includes a chopper and amplification unit 410ᵢ, a clock signal generator 420ᵢ, and a virtual ground voltage generator 430ᵢ. The chopper and amplification unit 410ᵢ includes chopper units 440ᵢ, 450ᵢ, and 460ᵢ, transistors 472ᵢ, 474ᵢ, 476ᵢ, 478ᵢ, 480ᵢ, 482ᵢ, 484ᵢ, 486ᵢ, 488ᵢ, and 490ᵢ, a resistor 412ᵢ, and a capacitor 414ᵢ. The chopper unit 440ᵢ includes transistors 442ᵢ, 444ᵢ, 446ᵢ, and 448ᵢ, the chopper unit 450ᵢ includes transistors 452ᵢ, 454ᵢ, 456ᵢ, and 458ᵢ, and the chopper unit 460ᵢ includes transistors 462ᵢ, 464ᵢ, 466ᵢ, and 468ᵢ. For example, i is an integer larger than or equal to 1 but smaller than or equal to N. As an example, N is a positive integer. Although the above has been shown using a selected group of components for the chopper amplifier 330ᵢ, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to some embodiments, the virtual ground voltage generator 430ᵢ receives the voltage 205, the ground voltage 271, a control voltage 433ᵢ and a reference current 435ᵢ and generates a virtual ground voltage 431ᵢ based at least in part on the voltage 205 according to some embodiments. For example, if the voltage 205 is lower than a predetermined threshold (e.g., 5 volts), the virtual ground voltage generator 430ᵢ generates the virtual ground voltage 431ᵢ that is equal to the ground voltage 271. As an example, if the voltage 205 is higher than the predetermined threshold (e.g., 5 volts), the virtual ground voltage generator 430ᵢ generates the virtual ground voltage 431ᵢ that is equal to the voltage 205 minus a predetermined value (e.g., 5 volts).

According to certain embodiments, the clock signal generator 420ᵢ receives the virtual ground voltage 431ᵢ, the ground voltage 271, the voltage 205, and a clock signal 421ᵢ and generates clock signals 423ᵢ, 425ᵢ, 427ᵢ and 429ᵢ based at least in part on the virtual ground voltage 431ᵢ, the ground voltage 271, the voltage 205, and the clock signal 421ᵢ. For example, if the clock signal 423ᵢ is at a logic high level, the clock signal 425ᵢ is at a logic low level, and if the clock signal 423ᵢ is at the logic low level, the clock signal 425ᵢ is at the logic high level. As an example, if the clock signal 427ᵢ is at the logic high level, the clock signal 429ᵢ is at the logic low level, and if the clock signal 427ᵢ is at the logic low level, the clock signal 429ᵢ is at the logic high level.

In some examples, the supply voltage 391 minus the ground voltage 271 is equal to 5 volts, and the voltage 205 minus the virtual ground voltage 431ᵢ, is also equal to 5 volts. For example, if the clock signal 423ᵢ is equal to the supply voltage 391, the clock signal 423ᵢ is at the logic high level, and if the clock signal 423ᵢ is equal to the ground voltage 271, the clock signal 423ᵢ is at the logic low level. As an example, if the clock signal 425ᵢ is equal to the supply voltage 391, the clock signal 425ᵢ is at the logic high level, and if the clock signal 425ᵢ is equal to the ground voltage 271, the clock signal 425ᵢ is at the logic low level. For example, if the clock signal 427ᵢ is equal to the voltage 205, the clock signal 427ᵢ is at the logic high level, and if the clock signal 427ᵢ is equal to the virtual ground voltage 431ᵢ, the clock signal 427ᵢ is at the logic low level. As an example, if the clock signal 429ᵢ is equal to the voltage 205, the clock signal 429ᵢ is at the logic high level, and if the clock signal 429ᵢ is equal to the virtual ground voltage 431ᵢ, the clock signal 429ᵢ is at the logic low level. In certain examples, each clock signal of the clock signals 423ᵢ, 425ᵢ, 427ᵢ and 429ᵢ has a duty cycle that is equal to 50%.

As shown in FIG. 4, the clock signals 423ᵢ, 425ᵢ, 427ᵢ and 429ᵢ are used by the chopper units 440ᵢ, 450ᵢ, and 460ᵢ according to certain embodiments. For example, the clock signals 427ᵢ and 429ᵢ are received by the chopper units 440ᵢ and 450ᵢ. As an example, the clock signals 423ᵢ and 425ᵢ are received by the chopper unit 460ᵢ.

In some embodiments, the chopper unit 440ᵢ is a high-voltage chopper unit, and the transistors 442ᵢ, 444ᵢ, 446ᵢ, and 448ᵢ provide four branches for the high-voltage chopper unit 440ᵢ. In certain examples, the transistors 442ᵢ, 444ᵢ, 446ᵢ, and 448ᵢ each are a PMOS transistor. For example, a gate terminal of the transistor 442ᵢ and a gate terminal of the transistor 448ᵢ both receive the clock signal 429ᵢ. As an example, a gate terminal of the transistor 444ᵢ and a gate terminal of the transistor 446ᵢ both receive the clock signal 427ᵢ. In some examples, a source terminal of the transistor 442ᵢ and a source terminal of the transistor 446ᵢ are connected to the source terminal of the transistor 310ᵢ, and a source terminal of the transistor 444ᵢ and a source terminal of the transistor 448ᵢ are connected to the source terminal of the transistor 320ᵢ. For example, a drain terminal of the transistor 442ᵢ and a drain terminal of the transistor 444ᵢ are connected to a source terminal of the transistor 472ᵢ. As an example, a drain terminal of the transistor 446ᵢ and a drain terminal of the transistor 448ᵢ are connected to a source terminal of the transistor 474ᵢ.

In certain embodiments, the chopper unit 450ᵢ is a high-voltage chopper unit, and the transistors 452ᵢ, 454ᵢ, 456ᵢ, and 458ᵢ provide four branches for the high-voltage chopper unit 450ᵢ. In certain examples, the transistors 452ᵢ, 454ᵢ, 456ᵢ, and 458ᵢ each are a PMOS transistor. For example, a gate terminal of the transistor 452ᵢ and a gate terminal of the transistor 458ᵢ both receive the clock signal 429ᵢ. As an example, a gate terminal of the transistor 454ᵢ and a gate terminal of the transistor 456ᵢ both receive the clock signal 427ᵢ. In some examples, a source terminal of the transistor 452ᵢ and a source terminal of the transistor 456ᵢ are connected to a drain terminal of the transistor 472ᵢ, and a source terminal of the transistor 454ᵢ and a source terminal of the transistor 458ᵢ are connected to a drain terminal of the transistor 474ᵢ. For example, a drain terminal of the transistor 452ᵢ and a drain terminal of the transistor 454ᵢ are connected to a source terminal of the transistor 476ᵢ. As an example, a drain terminal of the transistor 456ᵢ and a drain terminal of the transistor 458ᵢ are connected to a source terminal of the transistor 478ᵢ.

In some embodiments, the chopper unit 460ᵢ is a low-voltage chopper unit, and the transistors 452ᵢ, 454ᵢ, 456ᵢ, and 458ᵢ provide four branches for the low-voltage chopper unit 460ᵢ. In certain examples, the transistors 462ᵢ, 464ᵢ, 466ᵢ, and 468ᵢ each are an NMOS transistor. For example, a gate terminal of the transistor 462ᵢ and a gate terminal of the transistor 468ᵢ both receive the clock signal 423ᵢ. As an example, a gate terminal of the transistor 464ᵢ and a gate terminal of the transistor 466ᵢ both receive the clock signal 425ᵢ. In some examples, a drain terminal of the transistor 462ᵢ and a drain terminal of the transistor 466ᵢ are connected to a source terminal of the transistor 484ᵢ, and a drain terminal of the transistor 464ᵢ and a drain terminal of the transistor 468ᵢ are connected to a source terminal of the transistor 486ᵢ. For example, a source terminal of the transistor 462ᵢ and a source terminal of the transistor 464ᵢ are connected to a drain terminal of the transistor 488ᵢ. As an example, a source terminal of the transistor 466ᵢ and a source terminal of the transistor 468ᵢ are connected to a drain terminal of the transistor 490ᵢ.

In certain examples, the transistors 472ᵢ and 474ᵢ each are a PMOS transistor (e.g., a low-voltage PMOS transistor). For example, a gate terminal of the transistor 472ᵢ and a gate terminal of the transistor 474ᵢ both receive a control signal 473ᵢ. In some examples, the transistors 476ᵢ and 478ᵢ each are a PMOS transistor (e.g., a high-voltage PMOS transistor). For example, a gate terminal of the transistor 476ᵢ and a gate terminal of the transistor 478ᵢ both receive a control signal 477ᵢ. In certain examples, the transistors 480, and 482, each are an NMOS transistor (e.g., a high-voltage NMOS transistor). For example, a gate terminal of the transistor 480ᵢ and a gate terminal of the transistor 482ᵢ both receive a control signal 481ᵢ. As an example, a drain terminal of the transistor 480ᵢ is connected to a drain terminal of the transistor 476ᵢ, and a drain terminal of the transistor 482ᵢ is connected to a drain terminal of the transistor 478ᵢ. In some examples, the transistors 484ᵢ and 486ᵢ each are an NMOS transistor (e.g., a low-voltage NMOS transistor). For example, a gate terminal of the transistor 484ᵢ and a gate terminal of the transistor 486ᵢ both receive a control signal 485ᵢ. As an example, a drain terminal of the transistor 484ᵢ is connected to a source terminal of the transistor 480ᵢ, and a drain terminal of the transistor 486ᵢ is connected to a source terminal of the transistor 482ᵢ. In certain examples, the transistors 488ᵢ and 490ᵢ each are an NMOS transistor (e.g., a low-voltage NMOS transistor). For example, a gate terminal of the transistor 488ᵢ and a gate terminal of the transistor 490ᵢ both receive a control signal 489ᵢ. As an example, a source terminal of the transistor 488, and a source terminal of the transistor 490ᵢ both are biased to the ground voltage 271.

According to certain embodiments, if the clock signal 421ᵢ is at the logic high level, the clock signal generator 420ᵢ generates the clock signals 423ᵢ and 427ᵢ at the logic high level and the clock signals 425ᵢ and 429ᵢ at the logic low level. For example, if the clock signal 421ᵢ is at the logic high level, the transistors 442ᵢ, 472ᵢ, 452ᵢ, 476ᵢ, 480ᵢ, 484ᵢ, 462ᵢ, and 488ᵢ are turned on, allowing a current to flow from the source terminal of the transistor 310ᵢ. As an example, if the clock signal 421ᵢ is at the logic high level, the transistors 448ᵢ, 474ᵢ, 458ᵢ, 478ᵢ, 482ᵢ, 486ᵢ, 468ᵢ, and 490ᵢ are also turned on, allowing a current to flow from the source terminal of the transistor 320ᵢ.

According to some embodiments, if the clock signal 421ᵢ is at the logic low level, the clock signal generator 420ᵢ generates the clock signals 423ᵢ and 427ᵢ at the logic low level and the clock signals 425ᵢ and 429ᵢ at the logic high level. For example, if the clock signal 421ᵢ is at the logic low level, the transistors 446ᵢ, 474ᵢ, 454ᵢ, 476ᵢ, 480ᵢ, 484ᵢ, 466ᵢ, and 490ᵢ are turned on, allowing a current to flow from the source terminal of the transistor 310ᵢ. As an example, if the clock signal 421ᵢ is at the logic low level, the transistors 444ᵢ, 472ᵢ, 456ᵢ, 478ᵢ, 482ᵢ, 486ᵢ, 464ᵢ, and 488ᵢ are also turned on, allowing a current to flow from the source terminal of the transistor 320ᵢ.

In certain examples, if the clock signal 421ᵢ changes from the logic high level to the logic low level, the transistors 472ᵢ and 488ᵢ change from receiving the current that flows from the source terminal of the transistor 310ᵢ to receiving the current that flows from the source terminal of the transistor 320ᵢ, and the transistors 474ᵢ and 490ᵢ change from receiving the current that flows from the source terminal of the transistor 320ᵢ to receiving the current that flows from the source terminal of the transistor 310ᵢ. In some examples, if the clock signal 421ᵢ changes from the logic low level to the logic high level, the transistors 472ᵢ and 488ᵢ change from receiving the current that flows from the source terminal of the transistor 320ᵢ to receiving the current that flows from the source terminal of the transistor 310ᵢ, and the transistors 474ᵢ and 490ᵢ change from receiving the current that flows from the source terminal of the transistor 310ᵢ to receiving the current that flows from the source terminal of the transistor 320ᵢ.

In certain embodiments, the transistors 472ᵢ, 474ᵢ, 488ᵢ and 490ᵢ are configured to perform amplification as parts of the chopper and amplification unit 410ᵢ. In some embodiments, the resistor 412ᵢ and the capacitor 414ᵢ are configured to perform low-pass filtering as parts of the chopper and amplification unit 410ᵢ.

As discussed above and further emphasized here, FIG. 4 is merely an example, which should not unduly limit the scope of the claims. One of ordinary skill in the art would recognize many variations, alternatives, and modifications. In some examples, the multiple chopper amplifiers do not share one clock signal generator and do not share one virtual ground voltage generator. For example, the chopper amplifier 330₁ and the chopper amplifier 330₂ do not share one clock signal generator and also do not share one virtual ground voltage generator. As an example, the clock signal generator 420₁ and the clock signal generator 420₂ are two separate clock signal generators, and the virtual ground voltage generator 4301 and the virtual ground voltage generator 430₂ are two separate virtual ground voltage generators. In certain examples, the multiple chopper amplifiers share one clock signal generator and/or share one virtual ground voltage generator. For example, the chopper amplifier 330₁ and the chopper amplifier 330₂ share one clock signal generator and also share one virtual ground voltage generator. As an example, the clock signal generator 420₁ and the clock signal generator 420₂ are one clock signal generator, and/or the virtual ground voltage generator 430₁ and the virtual ground voltage generator 430₂ are one virtual ground voltage generator.

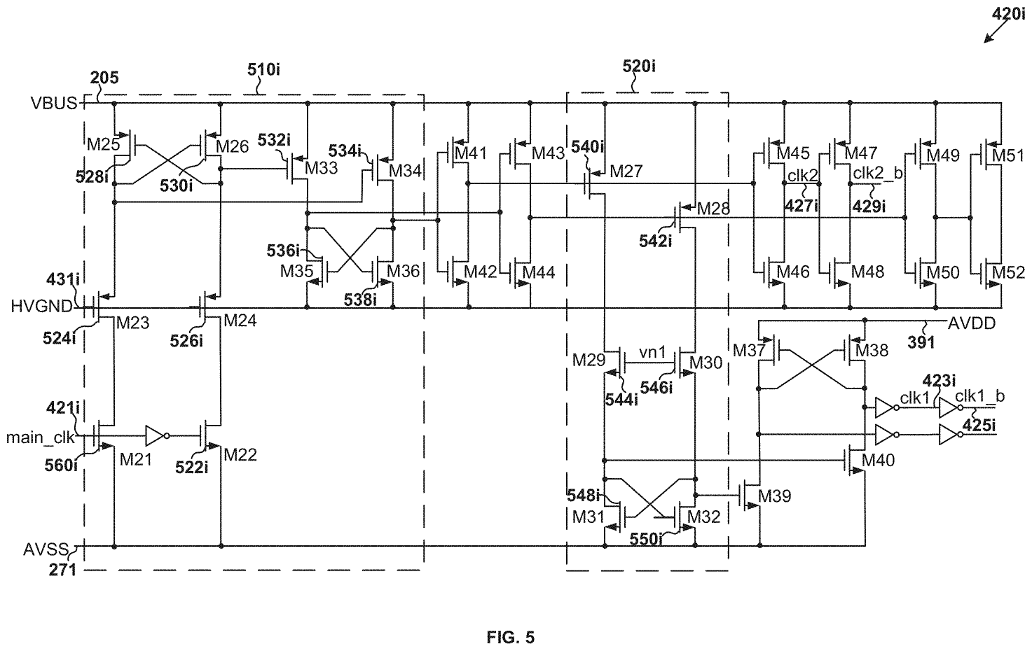

FIG. 5 is a simplified diagram showing certain components of the clock signal generator 420ᵢ of the chopper amplifier 330ᵢ of the operational amplifier 220ᵢ of the current detection system as part of the charging system 200 as shown in FIG. 2, FIG. 3 and FIG. 4 according to certain embodiments of the present invention. This diagram is merely an example, which should not unduly limit the scope of the claims. One of ordinary skill in the art would recognize many variations, alternatives, and modifications. The clock signal generator 420ᵢ includes a voltage converter 510ᵢ and a voltage converter 520ᵢ. The voltage converter 510ᵢ includes transistors 560ᵢ, 522ᵢ, 524ᵢ, 526ᵢ, 528ᵢ, 530ᵢ, 532ᵢ, 534ᵢ, 536ᵢ, and 538ᵢ.

The voltage converter 520ᵢ includes transistors 540ᵢ, 542ᵢ, 544ᵢ, 546ᵢ, 548ᵢ, and 550ᵢ. For example, i is an integer larger than or equal to 1 but smaller than or equal to N. As an example, N is a positive integer. Although the above has been shown using a selected group of components for the clock signal generator 420ᵢ, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

In some embodiments, the voltage converter 510ᵢ is used in order to convert the clock signal 421ᵢ to the clock signal 427ᵢ. For example, the logic high level of the clock signal 421ᵢ corresponds to the supply voltage 391, and the logic low level of the clock signal 421ᵢ corresponds to the ground voltage 271. As an example, the logic high level of the clock signal 427ᵢ corresponds to the voltage 205, and the logic low level of the clock signal 427ᵢ corresponds to the virtual ground voltage 431ᵢ. In certain examples, the virtual ground voltage 431ᵢ is higher than or equal to the ground voltage 271. For example, the voltage converter 510ᵢ is a boost converter (e.g., a step-up converter). In some examples, the clock signal 427ᵢ is used to generate the clock signal 429ᵢ.

In certain embodiments, the voltage converter 520ᵢ is used in order to convert the clock signal 427ᵢ to the clock signal 423ᵢ. For example, the logic high level of the clock signal 427ᵢ corresponds to the voltage 205, and the logic low level of the clock signal 427ᵢ corresponds to the virtual ground voltage 431ᵢ. As an example, the logic high level of the clock signal 423ᵢ corresponds to the supply voltage 391, and the logic low level of the clock signal 423ᵢ corresponds to the ground voltage 271. In certain examples, the ground voltage 271 is lower than or equal to the virtual ground voltage 431ᵢ. For example, the voltage converter 520ᵢ is a buck converter (e.g., a step-down converter). In some examples, the clock signal 423ᵢ is used to generate the clock signal 425ᵢ.

According to some embodiments, the clock signal 423ᵢ changes from the logic low level to the logic high level and the clock signal 427ᵢ changes from the logic low level to the logic high at the same time, and the clock signal 423ᵢ changes from the logic high level to the logic low level and the clock signal 427ᵢ changes from the logic high level to the logic low at the same time.

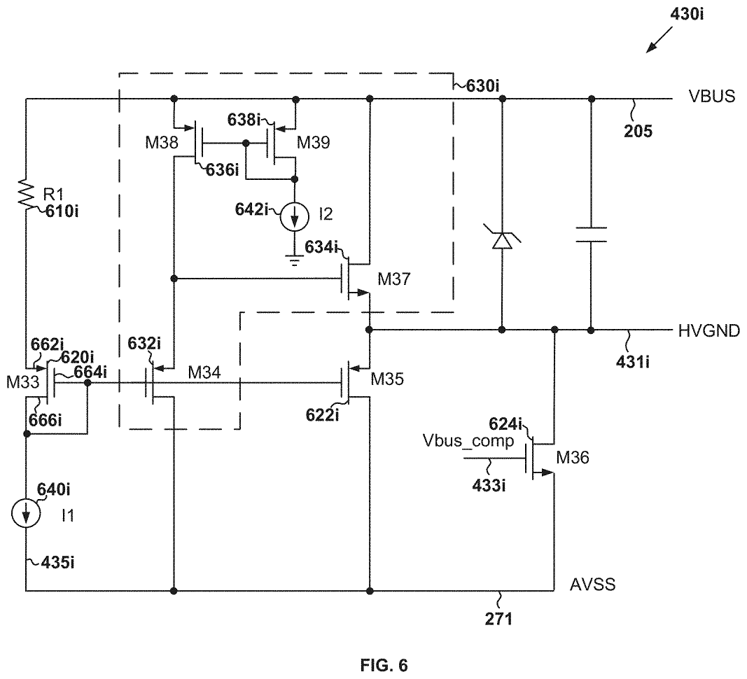

FIG. 6 is a simplified diagram showing certain components of the virtual ground voltage generator 430ᵢ of the chopper amplifier 330ᵢ of the operational amplifier 220ᵢ of the current detection system as part of the charging system 200 as shown in FIG. 2, FIG. 3 and FIG. 4 according to some embodiments of the present invention. This diagram is merely an example, which should not unduly limit the scope of the claims. One of ordinary skill in the art would recognize many variations, alternatives, and modifications. The virtual ground voltage generator 430ᵢ includes a resistor 610i, transistors 620ᵢ, 622ᵢ, and 624ᵢ, and a damper 630ᵢ. For example, i is an integer larger than or equal to 1 but smaller than or equal to N. As an example, N is a positive integer. Although the above has been shown using a selected group of components for the virtual ground voltage generator 430ᵢ, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

As shown in FIG. 6, the virtual ground voltage generator 430, receives the reference current 435ᵢ from a current source 640ᵢ according to certain embodiments. For example, the current source 640ᵢ is not a part of the virtual ground voltage generator 430ᵢ. In some examples, the damper 630, includes transistors 632ᵢ, 634ᵢ, 636ᵢ and 638ᵢ and a current source 642ᵢ. For example, the transistors 620ᵢ, 632ᵢ, and 622ᵢ are parts of a buffer. As an example, a gate terminal of the transistor 620ᵢ and a gate terminal of the transistor 622ᵢ are at the same voltage. In certain examples, the damper 630ᵢ is used to quickly clamp the virtual ground voltage 431ᵢ when the virtual ground voltage 431ᵢ decreases abruptly.

According to some embodiments, the virtual ground voltage generator 430ᵢ generates the virtual ground voltage 431ᵢ that is equal to the voltage 205 minus R₁×I_{ref}+V_{SG620i}, wherein R₁ represents the resistance of the resistor 610ᵢ, I_{ref} represents the reference current 435ᵢ, and V_{SG620i} represents a voltage at a source terminal of the transistor 620ᵢ minus a voltage at a gate terminal of the transistor 620ᵢ. For example, the transistor 620ᵢ includes the source terminal 662ᵢ, the gate terminal 664ᵢ, and a drain terminal 666ᵢ. As an example, V_{SG620i} represents the voltage at the source terminal 662ᵢ minus the voltage at the gate terminal 664ᵢ.

In some embodiments, a gate terminal of the transistor 624ᵢ receives the control voltage 433ᵢ. For example, if the voltage 205 is smaller than a predetermined threshold, the control voltage 433ᵢ is at a logic high level to turn on the transistor 624ᵢ. As an example, if the voltage 205 is larger than the predetermined threshold, the control voltage 433ᵢ is at a logic low level to turn off the transistor 624ᵢ.

In certain embodiments, the virtual ground voltage generator 430ᵢ generates the virtual ground voltage 431ᵢ as follows:

if V₂₀₅>Vₜₕ,

V₄₃₁ᵢ=V₂₀₅−(R₁×I_{ref}+V_{SG620i}) (Equation 5)

if V₂₀₅≤Vₜₕ,

V₄₃₁ᵢ=V₂₇₁ (Equation 6)

where V₂₀₅ represents the voltage 205, and Vₜₕ represents a predetermined threshold. Additionally, V₄₃₁ᵢ represents the virtual ground voltage 431ᵢ, and V₂₇₁ represents the ground voltage 271 that is equal to zero volts. Also, R₁ represents the resistance of the resistor 610ᵢ, and I_{ref} represents the reference current 435ᵢ. Additionally, V_{SG620i} represents the voltage at the source terminal 662ᵢ minus the voltage at the gate terminal 664ᵢ of the transistor 620ᵢ. For example, Vₜₕ is equal to 5 volts, and R₁×I_{ref}+V_{SG620i} is also equal to 5 volts. As an example, according to Equations 5 and 6, the virtual ground voltage 431ᵢ is higher than or equal to the ground voltage 271, which is equal to zero volts.

Certain embodiments of the present invention significantly decrease the number of resistors in a current detection system, therefore significantly reducing circuit loss and improving efficiency of a charging system that includes the current detection system. Some embodiments of the present invention provide a current detection system that includes an operational amplifier with at least one or more high-voltage chopper units and also includes a digital-to-analog converter (DAC) so that the current detection system performs precise current detection for a wide range of input voltage and/or output voltage of the power management system. For example, the input voltage of the power management system ranges from 3 volts to 48 volts. As an example, the output voltage of the power management system ranges from 3 volts to 48 volts. Certain embodiments of the present invention provide a current detection system that includes an operational amplifier with at least a clock signal generator that generates two clock signals at different voltage levels but completely synchronized in order to avoid chopping residue.

According to some embodiments, a system for detecting one or more currents includes: one or more current sampling units coupled to one or more terminal transistors respectively and configured to sample one or more terminal currents that flow between a system terminal of a power management system and one or more port terminals through the one or more terminal transistors respectively; one or more operational amplifiers coupled to the one or more current sampling units respectively and configured to generate one or more detection currents respectively, the one or more detection currents representing one or more magnitudes of the one or more terminal currents respectively; and a signal combiner configured to receive the one or more detection currents, generate a combined detection voltage representing a sum of the one or more magnitudes of the one or more terminal currents, and output the combined detection voltage to the power management system to regulate the sum of the one or more magnitudes of the one or more terminal currents. For example, the system for detecting one or more currents is implemented according to at least FIG. 2.

As an example, the one or more current sampling units include a first sampling unit; the one or more terminal transistors include a first terminal transistor; the one or more terminal currents include a first terminal current; the one or more port terminals include a first port terminal; the one or more operational amplifiers include a first operational amplifier; the one or more detection currents include a first detection current; and the one or more magnitudes of the one or more terminal currents include a first magnitude of the first terminal current. For example, the first current sampling unit is coupled to the first terminal transistor and configured to sample the first terminal current that flows between the system terminal of the power management system and the first port terminal through the first terminal transistor; and the first operational amplifier is coupled to the first current sampling unit and configured to generate the first detection current, the first detection current representing the first magnitude of the first terminal current. As an example, the one or more current sampling units include a second sampling unit; the one or more terminal transistors include a second terminal transistor; the one or more terminal currents include a second terminal current; the one or more port terminals include a second port terminal; the one or more operational amplifiers include a second operational amplifier; the one or more detection currents include a second detection current; and the one or more magnitudes of the one or more terminal currents include a second magnitude of the second terminal current. For example, the second current sampling unit is coupled to the second terminal transistor and configured to sample the second terminal current that flows between the system terminal of the power management system and the second port terminal through the second terminal transistor; and the second operational amplifier is coupled to the second current sampling unit and configured to generate the second detection current, the second detection current representing the second magnitude of the second terminal current. As an example, the signal combiner is further configured to receive at least the first detection current and the second detection current, generate the combined detection voltage representing the sum of at least the first magnitude of the first terminal current and the second magnitude of the second terminal current, and output the combined detection voltage to the power management system to regulate the sum of at least the first magnitude of the first terminal current and the second magnitude of the second terminal current.

For example, the first terminal transistor includes a first transistor terminal, a second transistor terminal, and a third transistor terminal; wherein: the second transistor terminal is connected to the system terminal of the power management system; and the third transistor terminal is connected to the first port terminal. As an example, the first sampling unit includes a first sampling transistor and a second sampling transistor; wherein: the first sampling transistor includes a fourth transistor terminal, a fifth transistor terminal, and a sixth transistor terminal; and the second sampling transistor includes a seventh transistor terminal, an eighth transistor terminal, and a ninth transistor terminal. For example, the fourth transistor terminal and the seventh transistor terminal each are connected to the first transistor terminal; the fifth transistor terminal is connected to the third transistor terminal; and the eighth transistor terminal is connected to the second transistor terminal.

As an example, the first operational amplifier includes a first amplifier terminal, a second amplifier terminal, and a third amplifier terminal; wherein: the first amplifier terminal is connected to the sixth transistor terminal of the first sampling transistor; and the second amplifier terminal is connected to the ninth transistor terminal of the second sampling transistor. For example, the first operational amplifier is further configured to generate the first detection current at the third amplifier terminal. As an example, wherein the first operational amplifier further includes: a chopper amplifier; a current mirror coupled to the chopper amplifier; and a digital-to-analog converter coupled to the current mirror. For example, the current mirror of the first operational amplifier is configured to output the first detection current.

According to certain embodiments, a chopper amplifier includes: a ground voltage generator configured to receive a first ground voltage and a system voltage and generate a second ground voltage based at least in part on the first ground voltage and the system voltage; a clock signal generator configured to receive an input clock signal, the first ground voltage and the second ground voltage and generate a first clock signal and a second clock signal based at least in part on the input clock signal, the first ground voltage and the second ground voltage; and a chopper and amplification unit including a first chopper unit, a second chopper unit coupled to the first chopper unit through multiple transistors, and a third chopper unit coupled to the second chopper unit through multiple transistors; wherein: the second ground voltage is higher than or equal to the first ground voltage; wherein: if the first clock signal is equal to the first ground voltage, the first clock signal is at a logic low level; and if the second clock signal is equal to the second ground voltage, the second clock signal is at the logic low level; wherein: the first chopper unit is configured to receive the second clock signal; the second chopper unit is configured to receive the second clock signal; and the third chopper unit is configured to receive the first clock signal. For example, the chopper amplifier is implemented according to at least FIG. 4.

As an example, a clock signal generator includes: a first voltage converter configured to, with one or more other components, convert the input clock signal to the second clock signal; and a second voltage converter configured to, with one or more other components, convert the second clock signal to the first clock signal. For example, the ground voltage generator is further configured to: if the system voltage is larger than a predetermined threshold, generate the second ground voltage to be equal to the system voltage minus a predetermined magnitude; and if the system voltage is smaller than the predetermined threshold, generate the second ground voltage to be equal to the first ground voltage.

According to some embodiments, a method for detecting one or more currents includes: sampling one or more terminal currents that flow between a system terminal of a power management system and one or more port terminals through one or more terminal transistors respectively; generating one or more detection currents representing one or more magnitudes of the one or more terminal currents respectively; receiving the one or more detection currents; generating a combined detection voltage representing a sum of the one or more magnitudes of the one or more terminal currents; and outputting the combined detection voltage to the power management system to regulate the sum of the one or more magnitudes of the one or more terminal currents. For example, the method for detecting one or more currents is implemented according to at least FIG. 2.

As an example, the one or more terminal transistors include a first terminal transistor; the one or more terminal currents include a first terminal current; the one or more port terminals include a first port terminal; the one or more detection currents include a first detection current; and the one or more magnitudes of the one or more terminal currents include a first magnitude of the first terminal current. For example, the sampling one or more terminal currents that flow between a system terminal of a power management system and one or more port terminals through one or more terminal transistors respectively includes sampling the first terminal current that flows between the system terminal of the power management system and the first port terminal through the first terminal transistor; and the generating one or more detection currents representing one or more magnitudes of the one or more terminal currents respectively includes generating the first detection current representing the first magnitude of the first terminal current. As an example, the receiving the one or more detection currents includes receiving at least the first detection current; and the generating a combined detection voltage representing a sum of the one or more magnitudes of the one or more terminal currents includes generating the combined detection voltage representing the sum of at least the first magnitude of the first terminal current. For example, the sum of the one or more magnitudes of the one or more terminal currents is equal to the first magnitude of the first terminal current.

In certain examples, some or all components of various embodiments of the present invention each are, individually and/or in combination with at least another component, implemented using one or more software components, one or more hardware components, and/or one or more combinations of software and hardware components. In some examples, some or all components of various embodiments of the present invention each are, individually and/or in combination with at least another component, implemented in one or more circuits, such as one or more analog circuits and/or one or more digital circuits. For example, the one or more current sampling units 210₁, 210₂, . . . , and 210_{N} each are implemented in one or more circuits. As an example, the chopper and amplification unit 410ᵢ is implemented in one or more circuits. For example, the chopper units 440ᵢ, 450ᵢ and 460ᵢ each are implemented in one or more circuits. As an example, various embodiments and/or examples of the present invention can be combined.

Although specific embodiments of the present invention have been described, it will be understood by those of skill in the art that there are other embodiments that are equivalent to the described embodiments. Accordingly, it is to be understood that the invention is not to be limited by the specific illustrated embodiments.

What is claimed is:

1. A system for detecting one or more currents, the system comprising:
one or more current sampling units coupled to one or more terminal transistors respectively and configured to sample one or more terminal currents that flow between a system terminal of a power management system and one or more port terminals through the one or more terminal transistors respectively;
one or more operational amplifiers coupled to the one or more current sampling units respectively and configured to generate one or more detection currents respectively, the one or more detection currents representing one or more magnitudes of the one or more terminal currents respectively; and
a signal combiner configured to receive the one or more detection currents, generate a combined detection voltage representing a sum of the one or more magnitudes of the one or more terminal currents, and output the combined detection voltage to the power management system to regulate the sum of the one or more magnitudes of the one or more terminal currents.

2. The system of claim 1 wherein:
the one or more current sampling units include a first sampling unit;
the one or more terminal transistors include a first terminal transistor;
the one or more terminal currents include a first terminal current;
the one or more port terminals include a first port terminal;
the one or more operational amplifiers include a first operational amplifier;
the one or more detection currents include a first detection current; and
the one or more magnitudes of the one or more terminal currents include a first magnitude of the first terminal current.

3. The system of claim 2 wherein:
the first current sampling unit is coupled to the first terminal transistor and configured to sample the first terminal current that flows between the system terminal of the power management system and the first port terminal through the first terminal transistor; and
the first operational amplifier is coupled to the first current sampling unit and configured to generate the first detection current, the first detection current representing the first magnitude of the first terminal current.

4. The system of claim 3 wherein:
the one or more current sampling units include a second sampling unit;
the one or more terminal transistors include a second terminal transistor;
the one or more terminal currents include a second terminal current;
the one or more port terminals include a second port terminal;
the one or more operational amplifiers include a second operational amplifier;
the one or more detection currents include a second detection current; and
the one or more magnitudes of the one or more terminal currents include a second magnitude of the second terminal current.

5. The system of claim 4 wherein:
the second current sampling unit is coupled to the second terminal transistor and configured to sample the second terminal current that flows between the system terminal of the power management system and the second port terminal through the second terminal transistor; and
the second operational amplifier is coupled to the second current sampling unit and configured to generate the second detection current, the second detection current representing the second magnitude of the second terminal current.

6. The system of claim 5 wherein the signal combiner is further configured to receive at least the first detection current and the second detection current, generate the combined detection voltage representing the sum of at least the first magnitude of the first terminal current and the second magnitude of the second terminal current, and output the combined detection voltage to the power management system to regulate the sum of at least the first magnitude of the first terminal current and the second magnitude of the second terminal current.

7. The system of claim 3 wherein:
the first terminal transistor includes a first transistor terminal, a second transistor terminal, and a third transistor terminal;
wherein:
the second transistor terminal is connected to the system terminal of the power management system; and
the third transistor terminal is connected to the first port terminal.

8. The system of claim 7 wherein:
the first sampling unit includes a first sampling transistor and a second sampling transistor;
wherein:
the first sampling transistor includes a fourth transistor terminal, a fifth transistor terminal, and a sixth transistor terminal; and
the second sampling transistor includes a seventh transistor terminal, an eighth transistor terminal, and a ninth transistor terminal.

9. The system of claim 8 wherein:
the fourth transistor terminal and the seventh transistor terminal each are connected to the first transistor terminal;
the fifth transistor terminal is connected to the third transistor terminal; and
the eighth transistor terminal is connected to the second transistor terminal.

10. The system of claim 8 wherein:
the first operational amplifier includes a first amplifier terminal, a second amplifier terminal, and a third amplifier terminal;
wherein:
the first amplifier terminal is connected to the sixth transistor terminal of the first sampling transistor; and
the second amplifier terminal is connected to the ninth transistor terminal of the second sampling transistor.

11. The system of claim 10 wherein the first operational amplifier is further configured to generate the first detection current at the third amplifier terminal.

12. The system of claim 10 wherein the first operational amplifier further includes:
a chopper amplifier;
a current mirror coupled to the chopper amplifier; and
a digital-to-analog converter coupled to the current mirror.

13. The system of claim 12 wherein the current minor of the first operational amplifier is configured to output the first detection current.

14. A chopper amplifier comprising:
a ground voltage generator configured to receive a first ground voltage and a system voltage and generate a second ground voltage based at least in part on the first ground voltage and the system voltage;
a clock signal generator configured to receive an input clock signal, the first ground voltage and the second ground voltage and generate a first clock signal and a second clock signal based at least in part on the input clock signal, the first ground voltage and the second ground voltage; and
a chopper and amplification unit including a first chopper unit, a second chopper unit coupled to the first chopper unit through multiple transistors, and a third chopper unit coupled to the second chopper unit through multiple transistors;
wherein:
the second ground voltage is higher than or equal to the first ground voltage;
wherein:
if the first clock signal is equal to the first ground voltage, the first clock signal is at a logic low level; and
if the second clock signal is equal to the second ground voltage, the second clock signal is at the logic low level;
wherein:
the first chopper unit is configured to receive the second clock signal;
the second chopper unit is configured to receive the second clock signal; and
the third chopper unit is configured to receive the first clock signal.

15. The chopper amplifier of claim 14 wherein a clock signal generator includes:
a first voltage converter configured to, with one or more other components, convert the input clock signal to the second clock signal; and
a second voltage converter configured to, with one or more other components, convert the second clock signal to the first clock signal.

16. The chopper amplifier of claim 14 wherein the ground voltage generator is further configured to:
if the system voltage is larger than a predetermined threshold, generate the second ground voltage to be equal to the system voltage minus a predetermined magnitude; and
if the system voltage is smaller than the predetermined threshold, generate the second ground voltage to be equal to the first ground voltage.

17. A method for detecting one or more currents, the method comprising:
sampling one or more terminal currents that flow between a system terminal of a power management system and one or more port terminals through one or more terminal transistors respectively;
generating one or more detection currents representing one or more magnitudes of the one or more terminal currents respectively;
receiving the one or more detection currents;
generating a combined detection voltage representing a sum of the one or more magnitudes of the one or more terminal currents; and
outputting the combined detection voltage to the power management system to regulate the sum of the one or more magnitudes of the one or more terminal currents.

18. The method of claim 17 wherein:
the one or more terminal transistors include a first terminal transistor;
the one or more terminal currents include a first terminal current;
the one or more port terminals include a first port terminal;
the one or more detection currents include a first detection current; and
the one or more magnitudes of the one or more terminal currents include a first magnitude of the first terminal current.

19. The method of claim 18 wherein:
the sampling one or more terminal currents that flow between a system terminal of a power management system and one or more port terminals through one or more terminal transistors respectively includes sampling the first terminal current that flows between the system terminal of the power management system and the first port terminal through the first terminal transistor; and
the generating one or more detection currents representing one or more magnitudes of the one or more terminal currents respectively includes generating the first detection current representing the first magnitude of the first terminal current.

20. The method of claim 19 wherein:
the receiving the one or more detection currents includes receiving at least the first detection current; and
the generating a combined detection voltage representing a sum of the one or more magnitudes of the one or more terminal currents includes generating the combined detection voltage representing the sum of at least the first magnitude of the first terminal current.

21. The method of claim 20 wherein the sum of the one or more magnitudes of the one or more terminal currents is equal to the first magnitude of the first terminal current.
